(19) United States
(12) Patent Application Publication
(10) Pub. No.: US 2026/0239799 A1
(43) Pub. Date: Aug. 13, 2026

(54) LIGHT-DIRECTING FEATURES IN LIGHT-EMITTING DIODE DEVICES

(71) Applicant: CreeLED, Inc., Durham, NC (US)

(72) Inventors: David Suich, Durham, NC (US); Michael Check, Holly Springs, NC (US); Joseph G. Sokol, Durham, NC (US); Colin Blakely, Raleigh, NC (US)

(21) Appl. No.: 19/049,151

(22) Filed: Feb. 10, 2025

(51) Int. Cl. H10H 29/855; H10H 29/24; H10H 29/85; H10H 29/852

(52) U.S. Cl. CPC H10H 29/855; H10H 29/24; H10H 29/852; H10H 29/857

(57) ABSTRACT

Light-emitting diode (LED) devices and more particularly light-directing features in LED packages and related devices are disclosed. Light-directing features include patterns or micropatterns in surfaces of light-directing layers to form features that tailor light emissions. LED packages include one or more LED chips, and light-directing features may be spatially tailored across LED package surfaces to provide increased far field emission uniformity. Certain LED packages include multiple LED chips such that some LED chips are positioned offset from center. Arrangements of light-directing features are disclosed that improve uniformity of LED chips positioned offset from center relative to LED chips centrally positioned.

### FIELD OF THE DISCLOSURE

The present disclosure relates to light-emitting diode (LED) devices and more particularly to light-directing features in LED packages and related devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices and more particularly to light-directing features in LED packages and related devices. Light-directing features include patterns or micropatterns in surfaces of light-directing layers to form features that tailor light emissions. LED packages include one or more LED chips, and light-directing features may be spatially tailored across LED package surfaces to provide increased far field emission uniformity. Certain LED packages include multiple LED chips such that some LED chips are positioned offset from center. Arrangements of light-directing features are disclosed that improve uniformity of LED chips positioned offset from center relative to LED chips centrally positioned.

In one aspect, an LED package comprises: one or more LED chips; a support element on which the one or more LED chips are mounted, wherein the support element is configured to be light-transmissive to wavelengths of light generated by the one or more LED chips; and a light-directing layer on a side of the support element that is opposite the one or more LED chips, the light-directing layer forming light-directing features at a light-exiting surface of the light-directing layer. In certain embodiments, the light-directing features comprise micropatterned features with largest dimensions that are less than 100 microns (μm). In certain embodiments, adjacent micropatterned features have a spacing of less than 30 μm. In certain embodiments, the light-directing features comprise at least one of rectangular pillars with flat top surfaces, rectangular pillars with angled top surfaces, cylindrical pillars with flat top surfaces, cylindrical pillars with angled top surfaces, pyramids, or truncated pyramids. In certain embodiments, the light-directing features form a sawtooth grating. In certain embodiments, the light-directing features comprise at least one of curved lenses, hemispheric lenses, oval lenses, or elongated lenses. In certain embodiments, the light-directing features form batwing structures. In certain embodiments, dimensions of the light-directing features vary laterally across the light-directing layer.

In certain embodiments: the one or more LED chips comprise a first LED chip and a second LED chip; and the light-directing features comprise a first group of light-directing features positioned proximate the first LED chip and a second group of light-directing features positioned proximate the second LED chip, wherein the first group of light-directing features comprises a different shape than the second group of light-directing features.

In certain embodiments: the one or more LED chips comprise a first LED chip, a second LED chip, and a third LED chip; and the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group of light-directing features comprise different shapes than the second group of light-directing features. In certain embodiments, dimensions of the first group of light-directing features progressively increase or decrease in a direction toward a perimeter edge of the support element.

In certain embodiments: the one or more LED chips comprise a first LED chip, a second LED chip, and a third LED chip, and the second LED chip is centrally positioned with respect to the first LED chip and the third LED chip; the light-directing features are positioned proximate the first LED chip and the third LED chip; and the light-directing layer forms a planar surface proximate the second LED chip.

In another aspect, an LED package comprises: a first pixel defined by a first grouping of LED chips; a second pixel defined by a second grouping of LED chips; a support element on which the first grouping of LED chips and the second grouping of LED chips are mounted, wherein the support element is configured to be light-transmissive to wavelengths of light generated by the first grouping of LED chips and the second grouping of LED chips; and a light-directing layer on a side of the support element that is opposite the first grouping of LED chips and the second grouping of LED chips, the light-directing layer forming light-directing features at a light-exiting surface of the light-directing layer.

In certain embodiments, the light-directing features comprise micropatterned features with largest dimensions that are less than 100 microns (μm). In certain embodiments, adjacent micropatterned features have a spacing of less than 30 μm. In certain embodiments: the first grouping of LED chips comprises a first LED chip, a second LED chip, and a third LED chip, and the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group comprise different shapes than the second group of light-directing features.

In another aspect, an LED display comprises: a display panel; and at least one LED package comprising; one or more LED chips; a support element on which the one or more LED chips are mounted, wherein the support element is configured to be light-transmissive to wavelengths of light generated by the one or more LED chips; and a light-directing layer on a side of the support element that is opposite the one or more LED chips, the light-directing layer forming light-directing features at a light-exiting surface of the light-directing layer. In certain embodiments, the light-directing features comprise micropatterned features with largest dimensions that are less than 100 microns (μm). In certain embodiments, adjacent micropatterned features have a spacing of less than 30 μm. In certain embodiments: the first grouping of LED chips comprises a first LED chip, a second LED chip, and a third LED chip; and the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group of light-directing features comprise different shapes than the second group of light-directing features.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A depicts a top view representation of a light-emitting diode (LED) package with multiple LED chips according to principles of the present disclosure.

FIG. 1B is a plot of an exemplary far field pattern for the LED package of FIG. 1A along the X-X viewing angle.

FIG. 1C is a plot of an exemplary far field pattern for the LED package of FIG. 1A along the Y-Y viewing angle.

FIG. 2A is a cross-sectional view of an LED package with a light-directing layer according to principles of the present disclosure.

FIG. 2B is a top view of the LED package of FIG. 2A.

FIG. 2C is a bottom view of the LED package of FIG. 2A.

FIG. 3 is a cross-sectional view of a portion of the light-directing layer of FIG. 2A for embodiments where the light-directing features form pillars that extend upward.

FIG. 4 is a cross-sectional view of a portion of the light-directing layer of FIG. 2A for embodiments where the light-directing features form triangular features that extend upward.

FIG. 5 is a cross-sectional view of a portion of the light-directing layer of FIG. 2A for embodiments where the light-directing features form curved lenses.

FIG. 6 is a cross-sectional view of a portion of the light-directing layer of FIG. 2A for embodiments where the light-directing features form trapezoidal cross-sections.

FIG. 7 is a cross-sectional view of a portion of the light-directing layer of FIG. 2A for embodiments where the light-directing features form pillars that extend upward with angled top surfaces.

FIG. 8 is a cross-sectional view of a portion of the light-directing layer of FIG. 2A for embodiments where the light-directing features form complex shapes such as batwings.

FIG. 9 is a cross-sectional view of a portion of the light-directing layer of FIG. 2A for embodiments where the light-directing features form gradient patterns.

FIG. 10 is a cross-sectional view of an LED package similar to the LED package of FIGS. 2A to 2C for embodiments where the light-directing features vary across the light-directing layer.

FIG. 11 is a cross-sectional view of an LED package similar to the LED package of FIG. 10 for embodiments where certain light-directing features have gradient dimensions.

FIG. 12 is a cross-sectional view of an LED package similar to the LED package of FIG. 10 for embodiments where light-directing features are only present proximate certain LED chips.

FIG. 13 is a cross-sectional view of an LED package similar to the LED package of FIG. 11 for embodiments where light-directing features are only present proximate certain LED chips.

FIG. 14 is a cross-sectional view of an LED package similar to the LED package of FIG. 10 for embodiments that include multiple pixels within the LED package.

FIG. 15 is a schematic diagram of a portion of an LED device that includes LED packages according to any of the embodiments described above for FIGS. 1A to 14.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices and more particularly to light-directing features in LED packages and related devices. Light-directing features include patterns or micropatterns in surfaces of light-directing layers to form features that tailor light emissions. LED packages include one or more LED chips, and light-directing features may be spatially tailored across LED package surfaces to provide increased far field emission uniformity. Certain LED packages include multiple LED chips such that some LED chips are positioned offset from center. Arrangements of light-directing features are disclosed that improve uniformity of LED chips positioned offset from center relative to LED chips centrally positioned.

Before delving into specific details for aspects of the present disclosure, an overview of various elements that may be included in exemplary LED devices and packages is provided for context. An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from various material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” or “light-transparent” when at least 80% of emitted radiation that impinges on the layer or region emerges through the layer or region. Moreover, as used herein, a layer or region of an LED is considered to be “reflective” or “light-reflective” or embody a “mirror” or a “reflector” when more than 50% or at least 80% of the emitted radiation that impinges on the layer or region is reflected. In the context of visible LEDs, the emitted radiation comprises visible light generated by a one or more LED chips, such as one or more of a blue LED, a green LED, and a red LED, among other visible wavelengths. In certain embodiments, a “light-transmissive” material may be configured to transmit at least 50% of emitted radiation of a desired wavelength. The terms transparent, reflective, and light-transmissive may be defined relative to certain wavelength ranges, such as those emitted by one or more LED chips and/or converted by any lumiphoric materials. Specific values listed above are meant to describe average values or properties of an element or layer. It is understood that variations of these properties may be present within or across such elements or layers.

As used herein, the term “opaque” refers to materials, surfaces, particles, among others, that are either not transparent or are non-light transmitting over at least a portion of the visible light spectrum. In certain aspects, the term “opaque” may also apply to the entire visible light spectrum. The term “non-light transmitting” may be considered as transmitting less than 20%, or less than 10% of a received light, or certain wavelengths of received light. A material may further be opaque due to either light absorption or light reflection. Some materials may be opaque at certain wavelengths and transparent at others.

The present disclosure can be useful for LED chips having a variety of geometries, such as lateral geometries. A lateral geometry LED chip typically includes both anode and cathode electrical connections on the same side of the LED chip that is opposite a substrate, such as a growth substrate. In certain embodiments, a lateral geometry LED chip may be flip-chip mounted such that the anode and cathode connections are on a face of the active LED structure that is opposite the primary emission face of the LED chip. In this configuration, electrical traces or patterns may be provided on a mounting surface for providing electrical connections to the anode and cathode connections of the LED chip. In a flip-chip configuration, the active LED structure is configured between the substrate of the LED chip and the mounting surface. Accordingly, light emitted from the active LED structure may pass through the substrate in a desired emission direction. The principles disclosed may also be applicable to other configurations, such as lateral geometries where anode and cathode electrical connections are made by way of topside wire bonds, or vertical geometries with anode and cathode connections made from opposing sides of the LED chip.

According to aspects of the present disclosure, LED packages may include one or more elements, such as lumiphoric materials, encapsulants, light-altering materials, lenses, superstrates or support elements, adhesive elements, and electrical contacts, among others, that are provided with one or more LED chips. Light-altering materials may be arranged within LED packages to reflect or otherwise redirect light from the one or more LED chips in a desired emission direction or pattern. Light-altering materials may also embody light-absorbing materials, such as opaque and/or black materials, that provide increased contrast. The term “superstrate” is used herein as a support element in an LED device, in part, to avoid confusion with other traditional substrates or submounts that may conventionally be part of LED devices, such as a growth or carrier substrate of the LED chip and/or a submount of an LED package. The term “superstrate” is not intended to limit the orientation, location, and/or composition of the structure it describes, nor various optical, electrical, thermal, and mechanical properties beyond the description of a support element as described herein. In certain embodiments, the superstrate may be composed of a transparent material, a semi-transparent material, or a light-transmissive material to various wavelengths of light provided by an LED chip and/or lumiphoric material.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), zirconium oxide (ZrO₂), aluminum oxide (Al₂O₃), metal particles, glass fibers and/or glass particles suspended in a binder, such as silicone or epoxy. In certain aspects, light-reflective particles may also be referred to as light-scattering particles. For light-absorbing materials, the light-altering material may include at least one of carbon, silicon, metal, metal oxides (e.g., iron oxides and the like) and organic particles suspended in a binder, such as silicone or epoxy. Exemplary organic particles may include various pigments, dyes, and/or absorptive additives. Thixotropic materials may include one or more of glass fillers and fumed silica. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray, for absorbing light and increasing contrast. In certain embodiments, the light-altering material includes both light-reflective material and light-absorbing material suspended in a binder. As used herein, a layer or coating of one or more light-altering materials may be referred to as a light-altering coating. In certain embodiments, a light-altering material or coating may be devoid of lumiphoric materials. In still further embodiments, light-altering materials may be provided in the form of coatings that are applied to outer sides or surfaces of light-emitting devices to control light emission.

In certain applications, it is desirable to increase the speed of manufacturing LED devices. One approach to increasing speed of manufacture is to assemble many LED packages on a single support element (or superstrate as described below) and later separate the groups into individual LED packages. This can be particularly useful when creating multi-color LED packages as pixels for use in high-definition (HD) video displays. Arrays of multi-color LED packages may be created as a large sheet and subsequently singulated into individual LED packages that each form a pixel for an LED display. Alternatively, larger singulated portions may result in an LED package with multiple LED pixels. In this manner, a single LED device, after singulation, may be populated with multiple LED chips of different emission colors, such as red, green, and blue, among others, as a single pixel. Such LED devices may be well suited for use as pixels within HD video displays and/or signage applications. In other embodiments, larger arrays of LED chips may be formed together to provide LED components, LED tiles, LED screens, and/or LED displays.

The elimination of various elements of a conventional LED device may streamline the manufacturing process, improve light quality, promote device miniaturization, and/or reduce costs. For example, LED devices can be assembled without the use of, or devoid of, a conventional LED package submount (e.g., a ceramic submount with traces, a lead frame structure, a printed circuit board, etc.). This may be accomplished by assembling the LEDs topside down, such that the LED chip is assembled on a support element, such as a transparent superstrate or a light-transmissive layer, which will become a topside outer surface in the finished product. The LED package can then be electrically connected through exposed electrical connection points on the opposite side of the LED chips. The device or apparatus may therefore be devoid of a traditional submount on the side of the LED chips opposite the light-transmitting side, such as, for example, a ceramic, metal, or other type of rigid material substrate upon which LEDs are often attached. An LED device built from the topside down as described herein can be considered a complete LED device, which is devoid of such a rigid underlying submount. That is not to say that such LED devices cannot later be assembled into a larger (e.g., multiple component) device, which can, for example, include a traditional package submount.

While such single LED devices with closely-spaced LED chips of multiple colors may be well suited for use as pixels within HD video displays and/or signage applications, challenges exist in near-field and/or far-field emission patterns from such devices. For example, nonmatching far-field emission patterns provided by different LED chips (e.g., red, blue, and green LED chips) in a single package may contribute to the appearance of a color shift when viewing at various angles. Emission variations can arise both from different emission patterns for the different color chips and from their geometrical placement within LED packages. In another example, near-field emissions are typically concentrated along a center of an LED device from closely-spaced LED chips, which contributes to a more pixelated appearance or reduced fill factor within video screens and displays. When multiple LED devices with centrally concentrated near-field emission patterns are assembled together, a so-called “screen door” effect may be visible when darker lines are formed in columns and rows along boundaries of the LED devices within the display.

According to principles of the present disclosure, support elements and associated light-directing features provide improved far-field emission patterns for increased uniformity at wider viewing angles within a display and/or improved near-field emission uniformity that increases the fill factor within each LED device, thereby reducing the screen door effect in the display. In certain aspects, light-directing features include micropatterned features at a light-exiting face of a package support element, such as features with heights and widths or diameters of less than 100 μm, or less than 50 μm, or less than 30 μm, and as low as 1 μm, or even into the sub-micron range, for example as low as 0.1 μm. Relative spacing for such light-directing features may be less than 30 μm or less than or equal to 20 μm, and as low as 10 μm, or 0.1 μm for sub-micron ranges in various embodiments. With such small sizes, the light-directing features may be readily incorporated at light-exiting surfaces of LED packages without added bulk associated with conventional lenses and/or reflectors. In the context of LED packages with multiple LED chips, such as red, green, and blue chips, light-directing features may be varied and/or aperiodic across the LED packages to steer emissions differently from each LED chip for improved light characteristics, such as more uniform far field emission patterns.

Light-directing features may be formed as part of a light-directing film applied to a surface of an LED package, such as a surface of a light-transparent support element or superstrate. The light-directing features may be formed by imprinting techniques that allow the smaller dimensions described above as compared to conventional injection molding techniques. By way of example, a light-directing film may include a layer of resin, such as polydimethylsiloxane (PDMS) or silicone that has been micropatterned by an imprinting process to form the light-directing features.

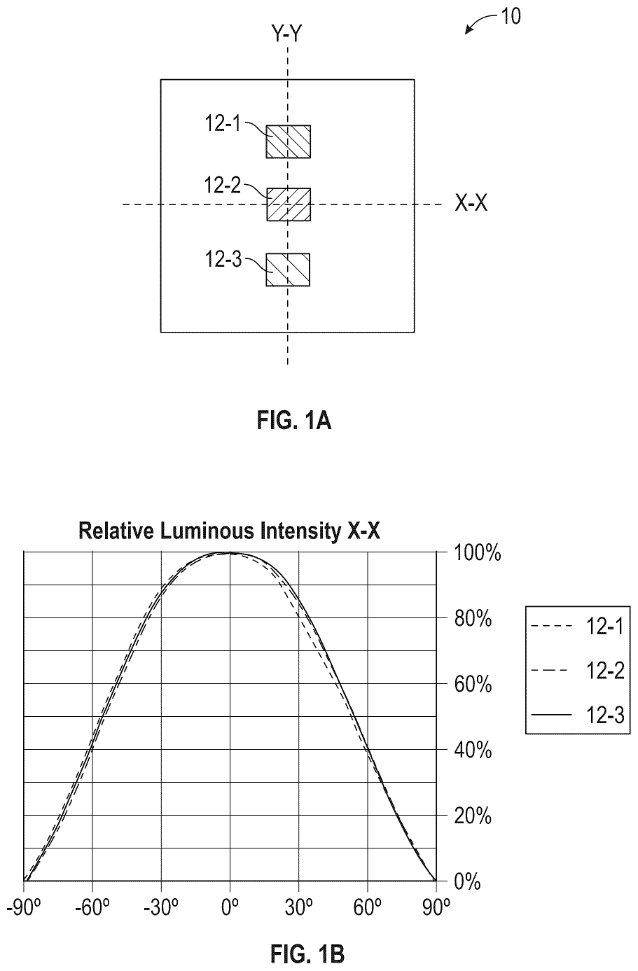

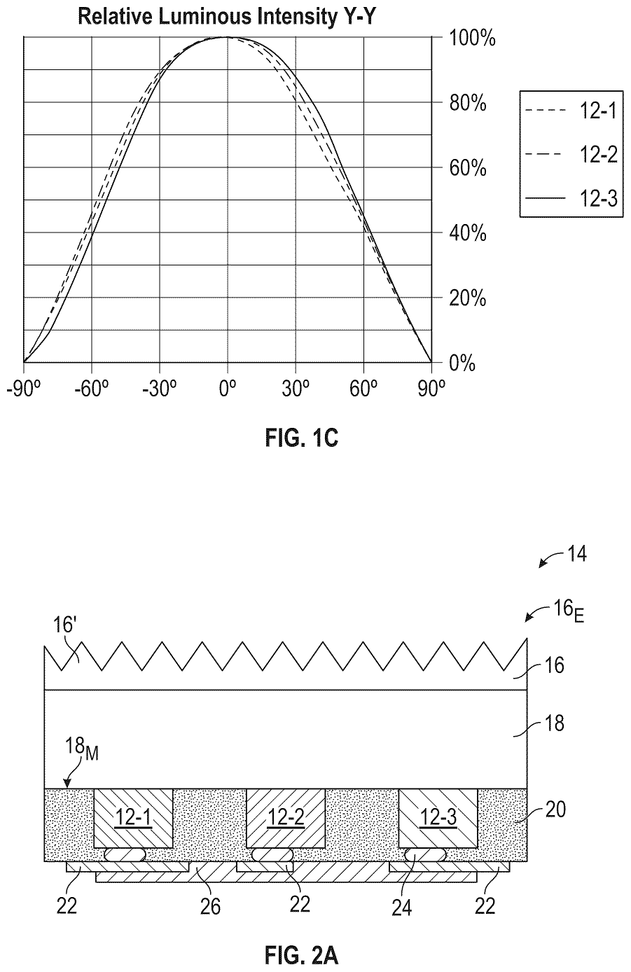

FIG. 1A depicts a top view representation of an LED package 10 with multiple LED chips 12-1 to 12-3 according to principles of the present disclosure. Superimposed dashed lines X-X and Y-Y respectively represent viewing angles that differ by 90 degrees, such as horizontal and vertical viewing angles. The X-X line or viewing angle may be referred to as the X-X axis and the Y-Y line or viewing angle may be referred to as the Y-Y axis for the LED package 10. In certain embodiments, the LED chips are arranged in a linear manner along the Y-Y viewing angle. In such an arrangement, the LED chip 12-2 may be centered with respect to both the X-X and Y-Y viewing angles while the other LED chips 12-1 and 12-3 are offset from center along the Y-Y view angle. While the multiple-chip LED package 10 may be well suited to form a pixel of an LED display, the offset nature of the LED chips 12-1 and 12-3 may create variations in overall emission patterns for the LED package 10. In the example where the LED chip 12-1 emits blue light, the LED chip 12-2 emits green light, and the LED chip 12-3 emits red light, the offset positioning of the LED chips 12-1 and 12-3 may create undesirable color variations and/or color shifts across various viewing angles in the far field pattern.

FIG. 1B is a plot of an exemplary far field pattern for the LED package 10 of FIG. 1A along the X-X viewing angle. The x-axis in FIG. 1B represents viewing angles in + and − degrees from center, or 0 degrees, and the y-axis represents relative luminous intensity for each LED chip 12-1 to 12-3 of FIG. 1A. Since the LED chips 12-1 to 12-3 of FIG. 1A are linearly aligned on the Y-Y axis, their relative positions are centered at 0 degrees with respect to the X-X viewing angle. Accordingly, the far field pattern for each LED chips 12-1 to 12-3 is similar, but some small variations are present.

FIG. 1C is a plot of an exemplary far field pattern for the LED package 10 of FIG. 1A along the Y-Y viewing angle. The x-axis in FIG. 1C represents viewing angles in + and − degrees from center, or 0 degrees, and the y-axis represents relative luminous intensity for each LED chip 12-1 to 12-3 of FIG. 1A. Since the LED chips 12-1 to 12-3 of FIG. 1A are linearly aligned on the Y-Y axis, the relative positions of the LED chips 12-1 and 12-3 are offset from 0 degrees with respect to the Y-Y viewing angle. Accordingly, larger variations in the far field pattern are present across various viewing angles.

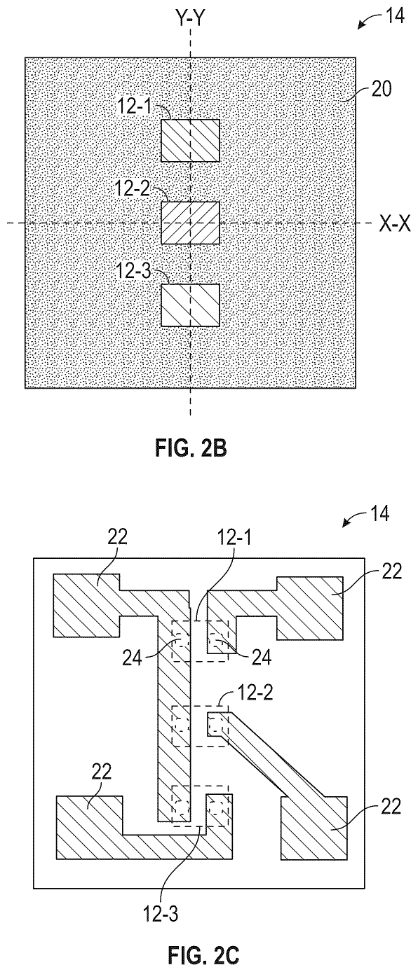

FIG. 2A is a cross-sectional view of an LED package 14 with a light-directing layer 16 according to principles of the present disclosure. By way of example, the LED package 14 embodies a top-down arrangement where the LED chips 12-1 to 12-3 are mounted to a support element 18 that receives light from the LED chips 12-1 to 12-3 in a desired emission direction. The support element 18, or superstrate, may comprise a light-transparent material that permits light from each of the LED chips 12-1 to 12-3 to freely pass therethrough. In certain embodiments, the light-transparent material of the support element 18 may comprise glass, sapphire, epoxy, or other hard materials that are light transparent to wavelengths of light generated by the LED chips 12-1 to 12-3.

The light-directing layer 16 is on a side of the support element 18 that is opposite the LED chips 12-1 to 12-3 and may comprise a light-transparent material relative to wavelengths of light emitted by the LED chips 12-1 to 12-3, such as silicone. The light-directing layer 16 may be imprinted to form light-directing features 16′ at a light-exiting surface 16E of the light-directing layer 16. As described above, the light-directing features 16′ may embody micropatterned features with largest dimensions, including heights, widths, and/or diameters that are less than 100 μm or less than 50 μm. Adjacent light-directing features 16′ may be formed with a spacing of less than 30 μm or less than or equal to 20 μm in various embodiments. Depending on their shape, location, and density, the light-directing features 16′ may effectively steer light from the LED chips 12-1 to 12-3 so that aggregate emissions from the LED package 14 have increased uniformity across multiple viewing angles, such as horizontal and vertical viewing angles. Moreover, an interface between the support element 18 and the light-directing layer 16 may backscatter some light at certain angles of incidence, thereby providing further improvements in color mixing. In FIG. 2A, the light-directing features 16′ extend continuously above all three LED chips 12-1 to 12-3. The light-directing features 16′ are also illustrated with uniform shapes, such as triangular cross-sections that may embody pyramids that protrude upward. In other embodiments as described later, the ability to imprint the light-directing features 16′ provides various options for varying shapes and sizes to tailor aggregate emission patterns, such as forming the light-directing features 16′ with non-uniform and/or aperiodic patterns, and/or selectively forming the light-directing features 16′ in certain areas of the LED package 14.

For illustrative purposes, three LED chips 12-1 to 12-3 are illustrated. However, the principles described are applicable to a single LED chip or any number of LED chips that are configured to emit the same or different wavelengths of light, depending on the embodiment. By way of example, for display applications where the LED package 14 forms a display pixel, three LED chips 12-1 to 12-3 may be provided that are configured to respectively emit blue light, green light, and red light. Other color combinations, inclusive of white emissions, may be provided depending on the application. Depending on the application, the LED chips 12-1 to 12-3 may have various lateral dimensions, such as in a range from 20 μm to 2,000 μm, or in a range from 20 μm to 1,000 μm, or in a range from 20 μm to 100 μm, or in a range from 100 μm to 2,000 μm. Miniature LED chips (e.g., around 100 μm to 300 μm+/−50 μm) and micro-LED chips (e.g., below 100 μm) may be well suited for pixels in LED displays.

As illustrated in FIG. 2A, the LED chips 12-1 to 12-3 are mounted to a mounting face 18M of the support element 18. The LED chips 12-1 to 12-3 are positioned to emit light into the support element 18 at the interface with the mounting face 18M. In certain embodiments, the LED chips 12-1 to 12-3 may embody flip-chip structures such that topsides of each LED chip 12-1 to 12-3 are attached to the mounting face 18M, and the topsides are devoid of electrical connections that would otherwise be in the light path.

After the LED chips 12-1 to 12-3 are adhered to the support element 18, an encapsulant layer 20 may be applied around a perimeter of and optionally between the LED chips 12-1 to 12-3. The encapsulant layer 20 may be applied by one or more of dispensing, molding, stenciling, screen printing, spinning, spraying, powder-coating, or slit coating. The encapsulant layer 20 may comprise electrically insulating materials, such as one or more of epoxy, epoxy-polyester hybrid, aliphatic urethane, triglycidyl isocyanurate (TGIC) polyester, non-TGIC polyester, silicone, silicone-modified polyester, silicone hybrid, silicone-epoxy hybrid, acrylic, polycarbonate, or any suitable combinations thereof. In certain embodiments, the encapsulant layer 20 may comprise a light-altering material used to control the light output of the LED package 14. For example, the encapsulant layer 20 may comprise light-reflective and/or light-refractive materials or particles to redirect light from the LED chips 12-1 to 12-3, or even light-absorbing materials that provide increased contrast. Certain light-reflective and/or light-refractive materials may exhibit a white appearance while light-absorbing materials may exhibit a dark or even black appearance. In certain embodiments, the encapsulant layer 20 may contain structures designed to increase its mechanical strength or other fillers designed to control the coefficient of thermal expansion (CTE). In the context of LED display applications, the encapsulant layer 20 may comprise a light-absorbing layer with a dark or black appearance to promote increased contrast between pixels.

Electrical connections for the LED chips 12-1 to 12-3 may be provided on sides of the LED chips 12-1 to 12-3 that are opposite the support element 18. Stated differently, the LED chips 12-1 to 12-3 may be arranged between the support element 18 and electrical connections for the LED chips 12-1 to 12-3. In this manner, at least a portion of light from the LED chips 12-1 to 12-3 may pass through the support element 18 without interacting with the electrical connections. The electrical connections may include electrically conductive traces that form device contact pads 22 electrically connected to one or more of the LED chips 12-1 to 12-3. The device contact pads 22 may include a single layer or multiple layers depending on the arrangement and/or manufacturing sequence. In certain embodiments, the device contact pads 22 may embody patterned metal traces. For example, the device contact pads 22 may be patterned such that segments thereof are electrically coupled with the one or more of the LED chips 12-1 to 12-3 and further extend on portions of the encapsulant layer 20. The LED chips 12-1 to 12-3 are electrically coupled to the device contact pads 22 by way of chip contact pads 24. In FIG. 2A, a single chip contact pad 24 is shown for each LED chip 12-1 to 12-3. It is appreciated that a second chip contact pad 24 for each LED chip 12-1 to 12-3 is present out of the cross-sectional plane viewable in FIG. 2A for flip-chip embodiments. In certain embodiments, a solder mask 26 may optionally be added to cover one or more portions of the device contact pads 22. In the cross-section of FIG. 2A, the device contact pad 22 for the LED chip 12-2 appears covered by the solder mask 26. It is appreciated that in certain cases, an extension of the device contact pad 22 for the LED chip 12-2 may be uncovered by the solder mask 26 in a different portion of the LED package 14 to facilitate external electrical connections.

FIG. 2B is a top view of the LED package 14 of FIG. 2A. For illustrative purposes, the support element 18 and the light-directing layer 16 of FIG. 2A are omitted. As illustrated, the encapsulant layer 20 may effectively surround all perimeter edges of each LED chips 12-1 to 12-3 so that light may preferentially escape through top surfaces of each LED chip 12-1 to 12-3 and into the support element 18 of FIG. 2A. From the top view, the LED chips 12-1 to 12-3 are illustrated in a linear arrangement similar to the LED package 10 of FIGS. 1A to 1C. However, the structure of the light-directing layer 16 provides the technical advantage of preferentially steering light as it exits the LED package 14 for improved far field uniformity in the X-X and Y-Y viewing angles.

FIG. 2C is a bottom view of the LED package 14 of FIG. 2A. For illustrative purposes, positions of the LED chips 12-1 to 12-3 and corresponding chip contact pads 24 are illustrated in dashed lines and the solder mask 26 of FIG. 2A is omitted. For flip-chip embodiments, each LED chip 12-1 to 12-3 includes a first chip contact pad 24 that may be mounted and electrically coupled to a common one of the device contact pads 22 and a second chip contact pad 24 that is mounted and electrically coupled to a different one of the device contact pads 22. Accordingly, the LED chips 12-1 to 12-3 may be electrically configured to be independently controlled with respect to one another.

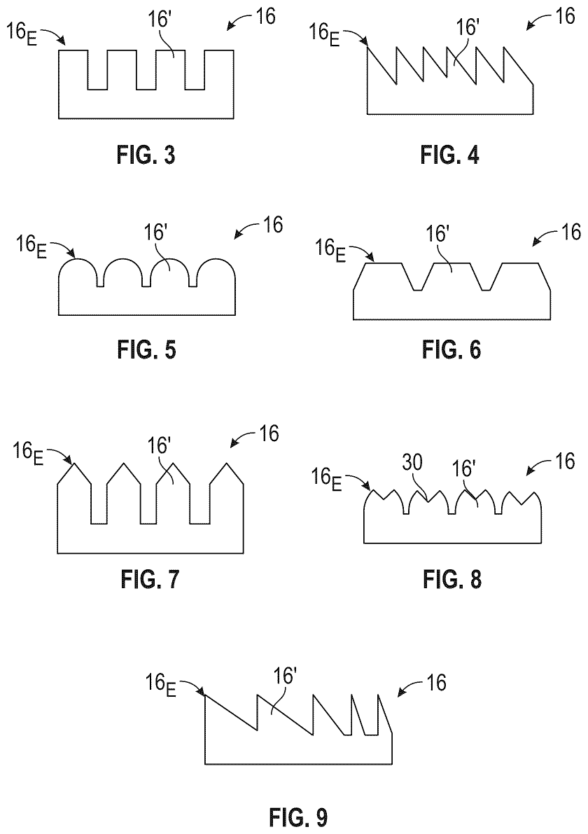

FIGS. 3 to 9 illustrates various configurations of light-directing features 16′ for the light-directing layer 16 of FIG. 2A. The ability to imprint the light-directing layer 16 enables various structures of the light-directing features 16′ to be readily formed. The views of the light-directing features 16′ in FIGS. 3 to 9 may be provided continuously across portions of the support element 18 of FIG. 2A to cover all of the LED chips 12-1 to 12-3. In other embodiments, the light-directing features 16′ in FIGS. 3 to 9 may be provided to cover only some of the LED chips 12-1 to 12-3 of FIG. 2A. In still other embodiments, different ones of the light-directing features 16′ in FIGS. 3 to 9 may be combined in a single LED package such that different ones of the LED chips 12-1 to 12-3 may be covered with different ones of the light-directing features 16′ of FIGS. 3 to 9.

FIG. 3 is a cross-sectional view of a portion of the light-directing layer 16 of FIG. 2A for embodiments where the light-directing features 16′ form pillars that extend upward. Depending on the desired emission pattern, the pillars may embody rectangular pillars, cylindrical pillars, or combinations thereof. In certain embodiments, the pillars may be formed with flat top surfaces to promote some backscattering of light at certain angles of incidence.

FIG. 4 is a cross-sectional view of a portion of the light-directing layer 16 of FIG. 2A for embodiments where the light-directing features 16′ form triangular features that extend upward. Depending on the desired emission pattern, the triangular features may form a sawtooth grating. In certain embodiments, the light-directing features 16′ may be uniformly sized and spaced to form the sawtooth grating.

FIG. 5 is a cross-sectional view of a portion of the light-directing layer 16 of FIG. 2A for embodiments where the light-directing features 16′ form curved lenses. Depending on the desired emission pattern, the curved lenses may embody hemispheric lenses, oval lenses, or elongated lenses. With the relatively small dimensions described above for micropatterning, the light-directing features 16′ may be referred to as a microlens array.

FIG. 6 is a cross-sectional view of a portion of the light-directing layer 16 of FIG. 2A for embodiments where the light-directing features 16′ form trapezoidal cross-sections. For example, the light-directing features 16′ may form truncated pyramids that extend upward.

FIG. 7 is a cross-sectional view of a portion of the light-directing layer 16 of FIG. 2A for embodiments where the light-directing features 16′ form pillars that extend upward with angled top surfaces. Depending on the desired emission pattern, the pillars may embody rectangular pillars, cylindrical pillars, or combinations thereof with angled top surfaces that reduce backscattering as compared with FIG. 3.

FIG. 8 is a cross-sectional view of a portion of the light-directing layer 16 of FIG. 2A for embodiments where the light-directing features 16′ form complex shapes such as batwings. As illustrated, one or more of the light-directing features 16′ may be formed with an angled indentation 30 along a top surface thereof that creates a generally batwing shape. Accordingly, some incident light at the angled indentation 30 may be redirected laterally to promote a batwing light distribution.

FIG. 9 is a cross-sectional view of a portion of the light-directing layer 16 of FIG. 2A for embodiments where the light-directing features 16′ form gradient patterns. By way of example, FIG. 9 is illustrated with a sawtooth grating similar to FIG. 4; however, dimensions of the light-directing features 16′ may vary in lateral directions across the light-directing layer 16. As illustrated, the relative widths of the light-directing features 16′ increase from right to left across the light-directing layer 16. The imprinted nature of the light-directing features 16′ allows the ability to vary dimensions to tailor emission patterns at various angles. While the triangular cross-sections were chosen for FIG. 9, the concept of gradient dimensions for the light-directing features 16′ is applicable to any of the shapes illustrated in FIGS. 2A and 3 to 8.

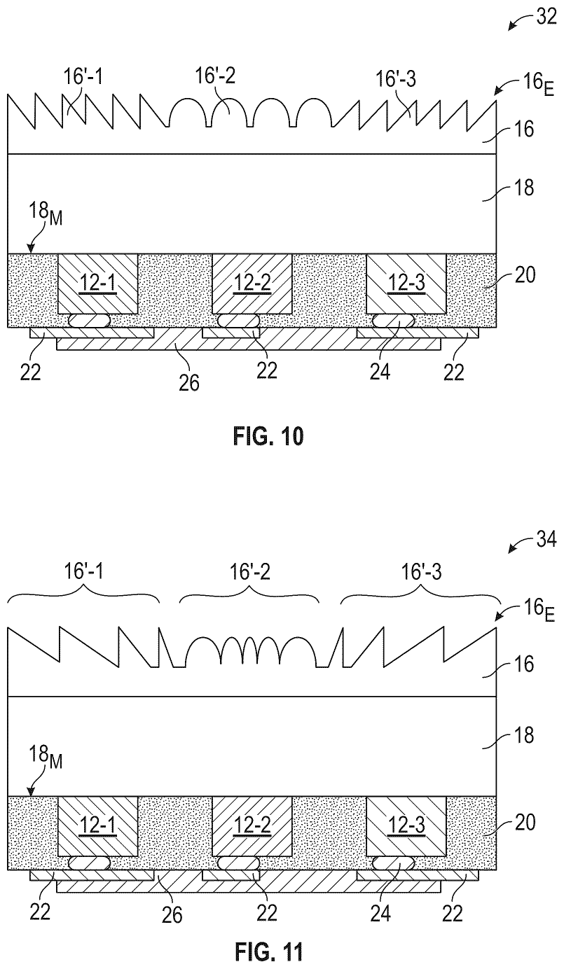

As described above, light-directing features of the present disclosure may be varied with respect to LED chips within a same LED package. Variations may be based on one or more of relative location of an LED chip relative to other LED chips, and emission patterns provided by each LED chip. FIGS. 10 to 14 illustrate various examples of varying light-directing features according to principles of the present disclosure. Other than the various patterns of light-directing features, the LED packages illustrated in FIGS. 10 to 14 may have the same or similar elements as described above for FIG. 2A to 2C. FIGS. 10 to 14 are described in the context of one or more groups of light-directing features that are positioned proximate certain LED chips. For example, a first group of light-directing features 16′-1 may be described as positioned proximate the LED chip 12-1 such that a vertical line extending perpendicular to the mounting face 18M of the support element would intersect the LED chip 12-1 and at least a portion of the first group of light-directing features 16′-1. Similar positional arrangements may be used for other groups of light-directing features 16′-2, 16′-3 respectively positioned proximate other LED chips 12-2, 12-3.

FIG. 10 is a cross-sectional view of an LED package 32 similar to the LED package 14 of FIGS. 2A to 2C for embodiments where the light-directing features vary across the light-directing layer 16. In FIG. 10, a first group of light-directing features 16′-1 is positioned proximate the LED chip 12-1 and a second group of light-directing features 16′-2 is positioned proximate the LED chip 12-2. The LED chip 12-1 is positioned offset from center relative to the LED package 32 and the first group of light-directing features 16′-1 may include a shape that directs increased amounts of light from the LED chip 12-1 toward a center of the LED package 32 for increased uniformity in a far field pattern of the LED chip 12-1 relative to the LED chip 12-2. A third group of light-directing features 16′-3 may be positioned proximate the LED chip 12-3. Since the LED chip 12-3 is also positioned offset from center, the third group of light-directing features 16′-3 may include a shape that also directs increased amounts of light from the LED chip 12-3 toward a center of the LED package 32 for increased uniformity in a far field pattern of the LED chip 12-3 relative to the LED chip 12-2. In the example of FIG. 10, the first group of light-directing features 16′-1 and the third group of light-directing features 16′-3 have similar cross-sectional shapes but differ in that they form mirror images of one another on opposing sides of the LED package 32. In certain embodiments, the second group of light-directing features 16′-2 may have a curved lens shape proximate the center of the LED package.

FIG. 11 is a cross-sectional view of an LED package 34 similar to the LED package 32 of FIG. 10 for embodiments where certain light-directing features have gradient dimensions. As illustrated, the first group of light-directing features 16′-1 is formed with dimensions, such as widths, that progressively increase in a direction toward a perimeter edge of the support element 18, thereby redirecting light differently the closer it gets to the perimeter edge of the LED package 34. In a similar manner, the third group of light-directing features 16′-3 is also formed with dimensions, such as widths, that progressively increase in a direction toward another perimeter edge of the support element 18. In certain embodiments, even the centrally located second group of light-directing features 16′-2 may also have dimensions that progressively increase away from center. It is appreciated the various groups of light-directing features 16′-1 to 16′-2 may alternatively have dimensions that progressively decrease in directions away from center, depending on the desired emission pattern.

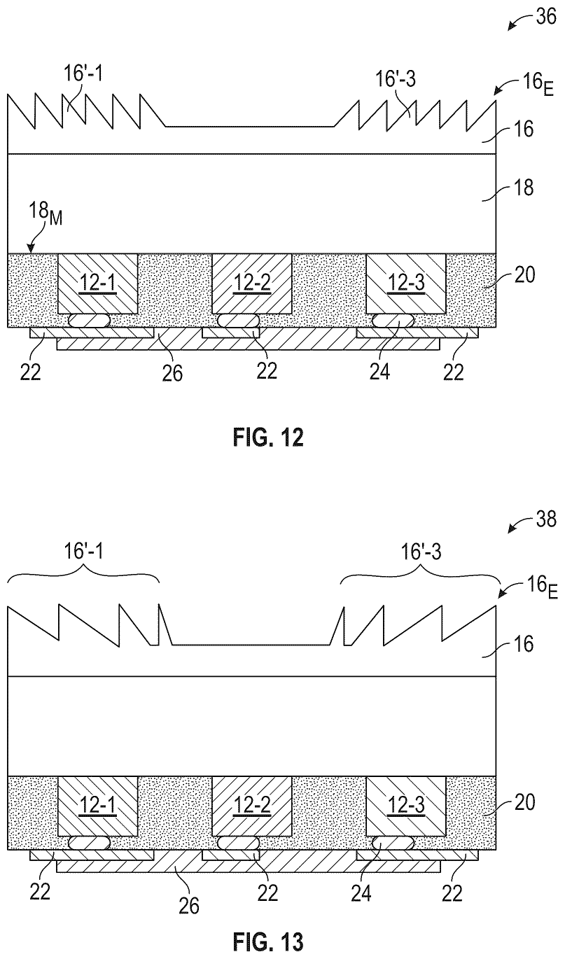

FIG. 12 is a cross-sectional view of an LED package 36 similar to the LED package 32 of FIG. 10 for embodiments where light-directing features 16′-1, 16′-3 are only present proximate certain LED chips 12-1, 12-2. Since the LED chip 12-2 is centrally positioned relative to the LED package 36, the light-directing layer 16 may form a generally planar surface proximate the LED chip 12-2. In such an arrangement, the light-directing features 16′-1, 16′-3 may be structured to respectively tune far field emission patterns for the LED chips 12-1 to 12-3 to have increased uniformity with respect to the LED chip 12-2.

FIG. 13 is a cross-sectional view of an LED package 38 similar to the LED package 34 of FIG. 11 for embodiments where light-directing features 16′-1, 16′-3 are only present proximate certain LED chips 12-1, 12-2. As with FIG. 12, the light-directing layer 16 may form a generally planar surface proximate the centrally positioned second LED chip 12-2. In such an arrangement, the light-directing features 16′-1, 16′-3 may be structured to respectively tune far field emission patterns for the LED chips 12-1 to 12-3 to have increased uniformity with respect to the LED chip 12-2.

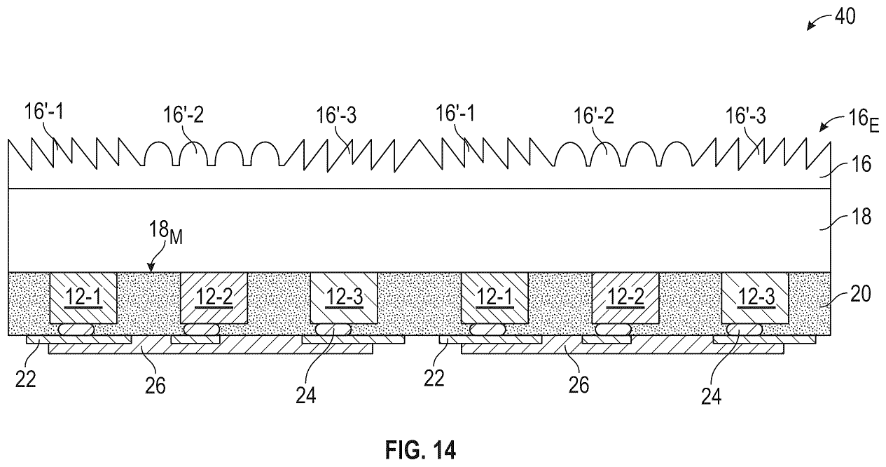

FIG. 14 is a cross-sectional view of an LED package 40 similar to the LED package 32 of FIG. 10 for embodiments that include multiple pixels within the LED package 40. As illustrated, the LED package 40 would effectively take the place of two of the LED packages 32 of FIG. 10. That is, two clusters or groupings of LED chips 12-1 to 12-3 may form two adjacent pixels for an LED display. The light-directing layer 16, the support element 18, and the encapsulant layer 20 may continuously extend across both clusters of LED chips 12-1 to 12-3. During fabrication, the LED package 40 may be formed in a similar manner as the LED package 32 of FIG. 10 but with singulation lines that define the two clusters of LED chips 12-1 to 12-3. The light-directing features 16′-1 to 16′-3 may provide increased far field uniformity for each individual pixel of LED chips 12-1 to 12-3, with the overall pattern of light-directing features 16′-1 to 16′-3 repeating for each pixel. While two pixels are shown for illustrative purposes, the principles described are applicable to any number of pixels in the LED package 40. Additionally, the principles described for FIG. 14 are also applicable to multiple-pixel embodiments for any of the LED packages of FIGS. 2A to 2C and 11 to 13.

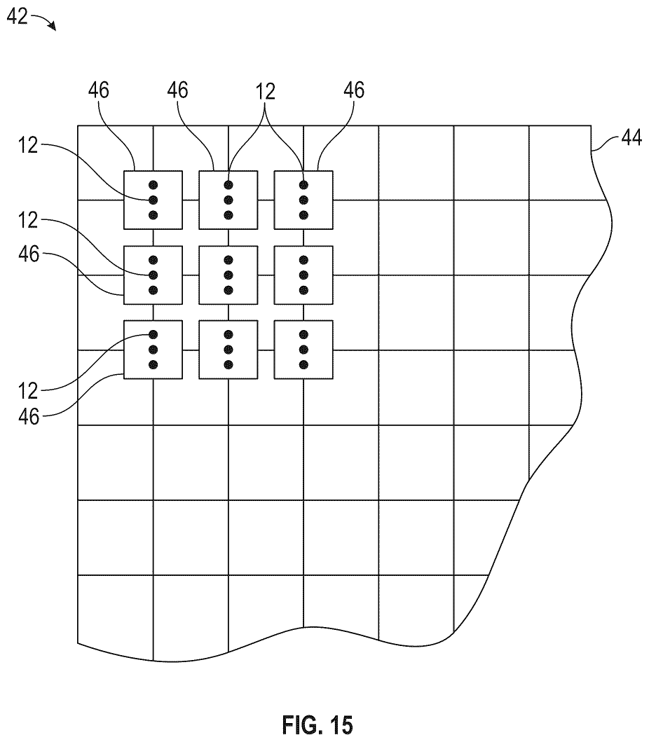

FIG. 15 is a schematic diagram of a portion of an LED device 42 that includes LED packages 46 according to any of the embodiments described above for FIGS. 1A to 14. The LED device 42 may embody an LED display screen, such as an indoor and/or outdoor screen comprising, in general terms, a display panel including a driver PCB 44 carrying a large number LED packages 46 in the form of surface-mount devices (SMDs) arranged in rows and columns, each LED package 46 defining at least one pixel. The LED packages 46 with LED chips 12 may embody any of the LED packages described above with respect to FIG. 1A-14. The LED packages 46 are electrically connected to traces or pads on the PCB 44 to respond to appropriate electrical signal processing and driver circuitry. As disclosed above, it is to be appreciated that while FIG. 15 depicts the LED chips 12 in a linear arrangement, in other embodiments, the LED chips 12 may be arranged in different configurations, such as a triangular layout. By forming light-directing layers with light-directing features as described above for any of FIG. 1A-14, pixels of the LED display screen may exhibit increased uniformity in far field patterns for each pixel. Accordingly, the LED device 42 may exhibit improved color rendering and contrast across larger viewing angles compared with conventional LED display screens.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
one or more LED chips;
a support element on which the one or more LED chips are mounted, wherein the support element is configured to be light-transmissive to wavelengths of light generated by the one or more LED chips; and
a light-directing layer on a side of the support element that is opposite the one or more LED chips, the light-directing layer forming light-directing features at a light-exiting surface of the light-directing layer.

2. The LED package of claim 1, wherein the light-directing features comprise micropatterned features with largest dimensions that are less than 100 microns (μm).

3. The LED package of claim 2, wherein adjacent micropatterned features have a spacing of less than 30 μm.

4. The LED package of claim 1, wherein the light-directing features comprise at least one of rectangular pillars with flat top surfaces, rectangular pillars with angled top surfaces, cylindrical pillars with flat top surfaces, cylindrical pillars with angled top surfaces, pyramids, or truncated pyramids.

5. The LED package of claim 1, wherein the light-directing features form a sawtooth grating.

6. The LED package of claim 1, wherein the light-directing features comprise at least one of curved lenses, hemispheric lenses, oval lenses, or elongated lenses.

7. The LED package of claim 1, wherein the light-directing features form batwing structures.

8. The LED package of claim 1, wherein dimensions of the light-directing features vary laterally across the light-directing layer.

9. The LED package of claim 1, wherein:
the one or more LED chips comprise a first LED chip and a second LED chip; and
the light-directing features comprise a first group of light-directing features positioned proximate the first LED chip and a second group of light-directing features positioned proximate the second LED chip, wherein the first group of light-directing features comprises a different shape than the second group of light-directing features.

10. The LED package of claim 1, wherein:
the one or more LED chips comprise a first LED chip, a second LED chip, and a third LED chip; and
the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group of light-directing features comprise different shapes than the second group of light-directing features.

11. The LED package of claim 10, wherein dimensions of the first group of light-directing features progressively increase or decrease in a direction toward a perimeter edge of the support element.

12. The LED package of claim 1, wherein:
the one or more LED chips comprise a first LED chip, a second LED chip, and a third LED chip, and the second LED chip is centrally positioned with respect to the first LED chip and the third LED chip;
the light-directing features are positioned proximate the first LED chip and the third LED chip; and
the light-directing layer forms a planar surface proximate the second LED chip.

13. A light-emitting diode (LED) package comprising:
a first pixel defined by a first grouping of LED chips;
a second pixel defined by a second grouping of LED chips;
a support element on which the first grouping of LED chips and the second grouping of LED chips are mounted, wherein the support element is configured to be light-transmissive to wavelengths of light generated by the first grouping of LED chips and the second grouping of LED chips; and
a light-directing layer on a side of the support element that is opposite the first grouping of LED chips and the second grouping of LED chips, the light-directing layer forming light-directing features at a light-exiting surface of the light-directing layer.

14. The LED package of claim 13, wherein the light-directing features comprise micropatterned features with largest dimensions that are less than 100 microns (μm).

15. The LED package of claim 14, wherein adjacent micropatterned features have a spacing of less than 30 μm.

16. The LED package of claim 13, wherein:
the first grouping of LED chips comprises a first LED chip, a second LED chip, and a third LED chip, and
the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group comprise different shapes than the second group of light-directing features.

17. A light-emitting diode (LED) display comprising:
a display panel; and
at least one LED package comprising;
one or more LED chips;
a support element on which the one or more LED chips are mounted, wherein the support element is configured to be light-transmissive to wavelengths of light generated by the one or more LED chips; and
a light-directing layer on a side of the support element that is opposite the one or more LED chips, the light-directing layer forming light-directing features at a light-exiting surface of the light-directing layer.

18. The LED package of claim 17, wherein the light-directing features comprise micropatterned features with largest dimensions that are less than 100 microns (μm).

19. The LED package of claim 18, wherein adjacent micropatterned features have a spacing of less than 30 μm.

20. The LED package of claim 17, wherein:
the first grouping of LED chips comprises a first LED chip, a second LED chip, and a third LED chip; and
the light-directing features comprise a first group of light-directing features positioned proximate the first LED chip, a second group of light-directing features positioned proximate the second LED chip, and a third group of light-directing features positioned proximate the third LED chip, wherein the first group of light-directing features and the third group of light-directing features comprise different shapes than the second group of light-directing features.
